(19) United States
(12) Patent Application Publication
(10) Pub. No.: US 2002/0079588 A1
(43) Pub. Date: Jun. 27, 2002

(54) Semiconductor device and method for manufacturing the same

(76) Inventors: Nam-Kyeong Kim, Ichon-shi (KR); Seung-Jin Yeom, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/025,913

(22) Filed: Dec. 26, 2001

(30) Foreign Application Priority Data
Dec. 26, 2000 (KR) 2000-82308

(51) Int. Cl. H01L 29/12; H01L 21/16; H01L 23/48

(52) U.S. Cl. 257/774; 257/43; 438/85; 438/86; 438/104; 257/751; 438/627; 438/629

(57) ABSTRACT

A method for manufacturing a semiconductor device comprises the steps of providing a semiconductor substrate, forming an interlayer insulating layer on the semiconductor substrate, forming a contact hole in the interlayer insulating layer, forming a plug recessed inside of the contact hole, forming an ohmic contact layer on the plug, depositing a La layer or a LaN layer on the ohmic contact layer, performing a nitridation process by a plasma treatment process to form a LaN diffusion barrier layer on the ohmic contact layer and sequentially forming a bottom electrode, a BLT ((BiₓLa_{y})Ti₃O₁₂) dielectric layer and a top electrode on the entire structure.

### FIELD OF THE INVENTION

The present invention relates to a semiconductor device and a method for manufacturing the same; and, more particularly, to a capacitor in a semiconductor device and its method for improving the electrical characteristics and reliability of the capacitor.

### DESCRIPTION OF THE PRIOR ART

Recently, an SBT (Sr₁Bi₂Ta₂O₉) layer, an SBTN (SrBi₂(Ta, Nb)O₉) layer and a BLT (BiₓLa_{y})Ti₃O₁₂ layer having a pervoskite structure and a Bi-layered characteristic have been developed as a dielectric layer of a capacitor in a nonvolatile memory device. Even if the dielectric layer of the SBT series has good reliability and properties as a dielectric layer in a capacitor in comparison with other ferroelectric materials, since a thermal treatment temperature of over 800° C. is required for crystallization of the SBT layer, serious oxidation of layers, such as a TiSi₂ ohmic contact layer, a plug or the like, which are previously formed in a capacitor, is generated in a device manufacturing process so that it is impossible to apply the BST layer in a highly integrated memory device using the plug.

To solve the above problem, the oxide layer of a BLT series, of which the crystallization temperature is lower than that of a SBT series, is employed. However, the BLT layer has to be thermally treated at a temperature of over 700° C. for crystallization in order to obtain the desired reliability for a capacitor. Accordingly, a diffusion barrier layer, which prevents the TiSi₂ ohmic contact layer and the plug from being oxidized in an oxygen atmosphere at a temperature of over 700° C., is required in the BLT capacitor.

FIG. 1 is a cross-sectional view showing a conventional semiconductor device having a BLT capacitor using a TiN diffusion barrier layer.

Referring to FIG. 1, an interlayer insulating layer 11 is formed on a transistor including a source/drain region, and a contact hole is formed by selectively etching the interlayer insulating layer 11 and then a plug 12 is formed with a polysilicon in the contact hole. A Ti layer is deposited on the plug 12 and then the ohmic contact layer 13 is formed by a thermal reaction of the Ti layer and the polysilicon plug 12. A TiN layer is deposited on the entire structure to form a diffusion barrier layer 14 and a planarization process of the structure is carried out in order that the TiN diffusion barrier layer remains only in the contact hole.

A bottom electrode 15 is formed on the interlayer insulating layer 11 and the TiN diffusion barrier layer and a BLT dielectric layer 16 and a top electrode 17 are sequentially formed. However, as mentioned above, since the BLT capacitor has to be thermally treated at a temperature of over 700° C., the plug 12 and the ohmic contact layer 13 are oxidized and surface peeling is caused so that the electrical characteristics and electrode property become deteriorated.

### SUMMARY OF THE INVENTION

It is, therefore, an object of the present invention to provide a semiconductor device and a method for improving the electrical characteristics, the charge capacity and the reliability of a capacitor in a semiconductor device.

In accordance with an aspect of the present invention, there is provided a method for manufacturing a semiconductor device, comprising the steps of: providing a semiconductor substrate; forming a contact hole and forming a plug recessed inside of the contact hole; forming an ohmic contact layer on the plug in the contact hole and depositing La or LaN on the ohmic contact layer; forming a LaN diffusion barrier layer nitrided by a plasma treatment in an ambient of nitrogen or ammonia in the contact hole; and forming a capacitor, including the steps of: forming a bottom electrode on the diffusion barrier layer and forming a BLT ((BiₓLa_{y})Ti₃O₁₂) dielectric layer on the bottom electrode; and forming a top electrode on the BLT dielectric layer.

In accordance with another aspect of the present invention, there is provided a semiconductor device, comprising: a semiconductor substrate; a transistor including a gate insulating layer and a gate electrode formed on the semiconductor substrate and a source/drain region formed in the semiconductor substrate; a contact hole exposing the source/drain region; a plug recessed at the inside of the contact hole; an ohmic contact layer formed on the plug; an LaN diffusion barrier layer formed on the ohmic contact layer; and a capacitor formed on the LaN diffusion barrier layer, wherein the capacitor includes: a bottom electrode; a dielectric layer formed with BLT ((BiₓLa_{y})Ti₃O₁₂) on the bottom electrode; and a top electrode formed on the dielectric layer.

### BRIEF DESCRIPTION OF THE DRAWINGS

The above and other objects and features of the instant invention will become apparent from the following description of preferred embodiments taken in conjunction with the accompanying drawings, in which:

FIG. 1 is a cross-sectional view showing a conventional semiconductor device having a BLT ((BiₓLa_{y})Ti₃O₁₂) capacitor using a TiN diffusion barrier layer according to the prior art; and

FIGS. 2A to 2E are cross-sectional views showing a process for manufacturing a semiconductor device according to the present invention.

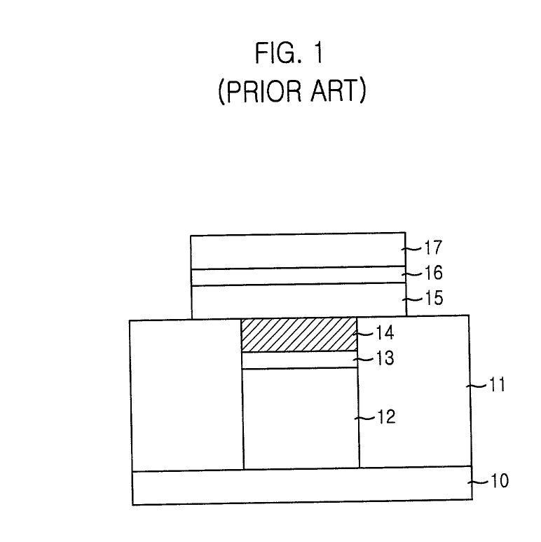

### DETAILED DESCRIPTION OF THE PREFERRED EMBODIMENTS

Hereinafter, a semiconductor capable of improving the electrical characteristics and electrode property and a method for manufacturing the same according to the present invention will be described in detail referring to the accompanying drawings.

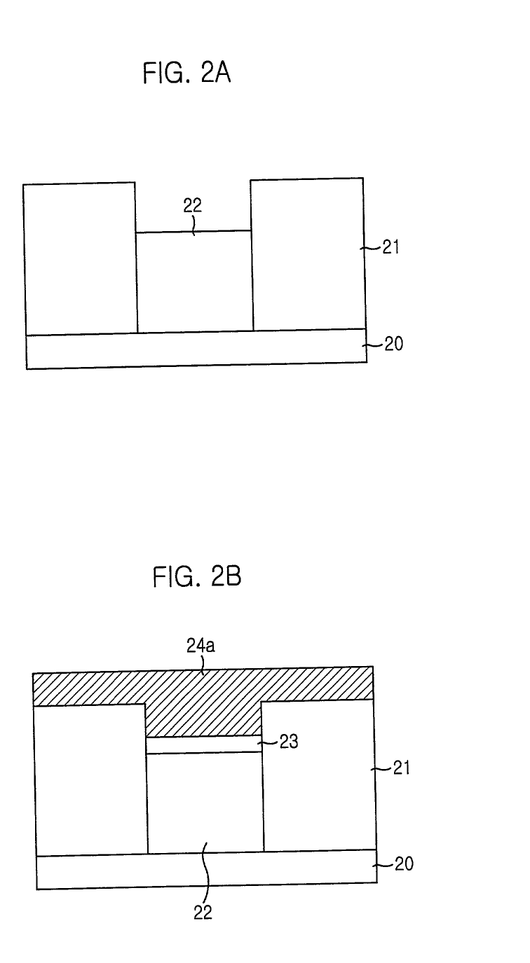

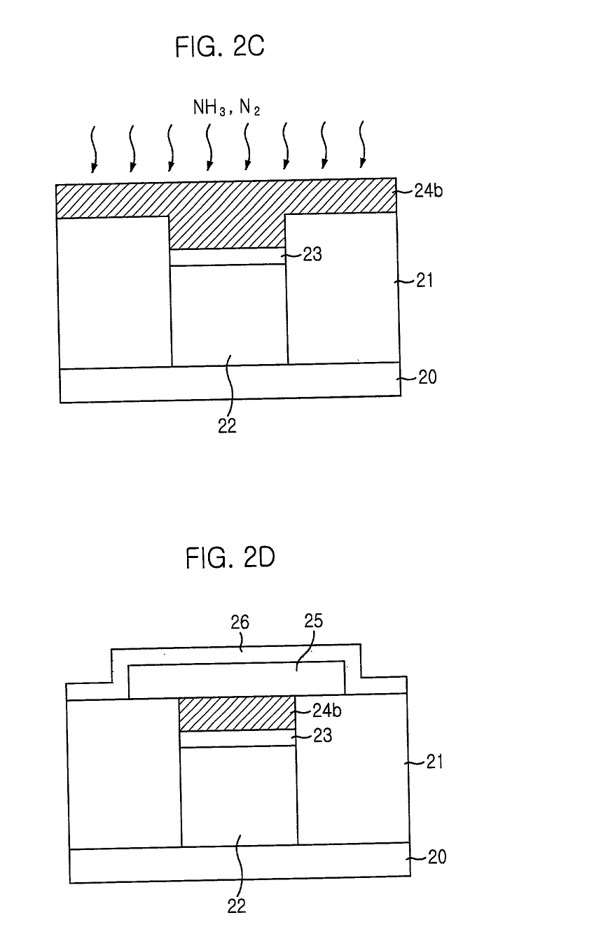

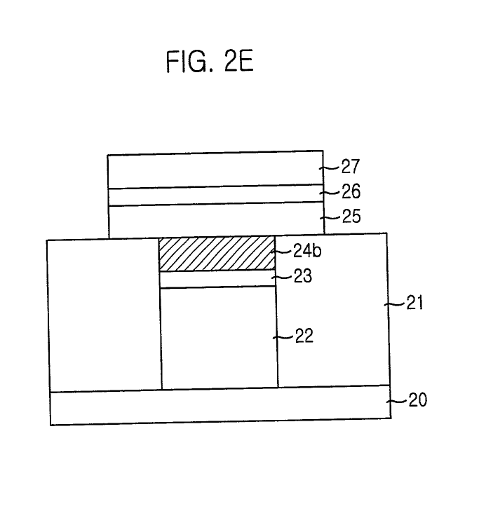

FIGS. 2A to 2E are cross-sectional views showing a process for manufacturing a semiconductor device according to the present invention.

Referring to FIG. 2A, an interlayer insulating layer 21 is formed on a transistor including a source/drain region, and a contact hole is formed by selectively etching the interlayer insulating layer 21. A plug 22 is formed by burying a polysilicon in the contact hole. At this time, an upper side of the contact hole is not filled with the plug 22. Herein, thin layers of a general oxide series may be applied as the interlayer insulating layer and multiple oxide layers may be used as the interlayer insulating layer in the memory device.

Referring to FIG. 2B, an ohmic contact layer 23, such as a TiSi₂ layer or the like, is formed on the plug 22 only in the contact hole and a La or LaN layer 24A is deposited on the entire structure. Herein, the width of the ohmic contact layer 23 is determined by the depth of a recess portion in the contact hole and other conditions after the plug 22 is formed, and the La layer 24A is formed at a thickness of 500 Å to 2000 Å.

A deposition process of the La or LaN layer 24A is performed by a deposition technique selected from the group consisting of pulse laser deposition (PLD), physical vapor deposition (PVD), metal organic chemical vapor deposition (MOCVD), sputtering, plasma enhanced metal organic chemical vapor deposition (PEMOCVD), liquid source mist chemical deposition (LSMCD) and atomic layer deposition (ALD).

Referring to FIG. 2C, the La or LaN layer 24A is crystallized through a plasma treatment process in a reduction atmosphere of a nitrogen (N₂) or ammonia (NH₃) gas and the LA layer nitrides at the same time so that, finally, a LaN diffusion barrier layer 24B is formed. Resistivity of the LaN layer is 100 μΩ/cm lower than that of the TiN layer. When atoms of the LaN layer are diffused into the BLT layer through a bottom electrode during a thermal treatment process, since the LaN layer includes an element of the BLT layer, the ferroelectric characteristic does not become deteriorated. The plasma treatment process is performed at a pressure of 1 mtorr to 10 torr, at a power of 25 W to 500 W and at a temperature of 250° C. to 650° C.

Subsequently, an etch back process or a chemical mechanical process (CMP) process is performed in order that the LaN layer remains only in the contact hole.

Referring to FIG. 2D, a bottom electrode is formed at a thickness of 500 Å to 2000 Å.

Referring to FIG. 2E, a BLT dielectric layer 26 is formed by which a BLT layer, in which the atomic concentration of Bi is 3.25 to 3.35 and the atomic concentration of La is 0.80 to 0.90, is deposited on the bottom electrode. After forming the BLT dielectric layer 26, a top electrode 27 is formed with a material selected from the group consisting of Ru, Pt, IrO₂ and RuOₓ (wherein, x is an integer from 1 to 3) by a deposition technique selected from the group consisting of MOCVD, PVD, spin-on and PECVD.

The BLT dielectric layer is formed by a deposition technique selected from the group consisting of spin-on, MOD, PVD, MOCVD, PECVD, LSMCD and ALD.

The PEMOCVD process is generally performed at a pressure of 5 mtorr to 50 torr and at a temperature of 400° C. to 700° C.

In using the MOD technique, the BLT layer is deposited by a first thermal treatment process, which is a rapid thermal process (RTP) increasing in speed from 80° C./second to 300° C./second with a reaction gas selected from the group consisting of an oxygen gas, a N₂O gas and a mixture gas of an oxygen gas and a nitrogen gas. Subsequently, the BLT layer is crystallized by a second thermal treatment, which is performed at a temperature of 650° C. to 675° C. and in an atmosphere selected from the group consisting of an oxygen gas, a N₂O gas and a mixture gas of oxygen and N₂O, so that the BLT dielectric layer 26 is finally formed.

The capacitor is formed as various types, such as a cylinder type, a concave type or the like, instead of a flat type.

As the LaN diffusion barrier layer is formed by the plasma treatment process in a reduction atmosphere of a nitrogen gas or an ammonia gas after the LaN layer is formed by depositing a La layer, which is a diffusion barrier layer, oxidation of the plug and the ohmic contact layer can be prevented so that the electrical characteristics, the electrode properties and reliability of the capacitor can be improved.

While the present invention has been described with respect to the particular embodiments, it will be apparent to those skilled in the art that various changes and modifications may be made without departing from the spirit and scope of the invention as defined in the following claims.

What is claimed is:

1. A method for manufacturing a semiconductor device, comprising the steps of:
providing a semiconductor substrate;
forming an interlayer insulating layer on the semiconductor substrate;
forming a contact hole in the interlayer insulating layer;
forming a plug recessed inside the contact hole;
forming an ohmic contact layer on the plug;
depositing a layer selected from the group consisting of an La layer and a LaN layer on the ohmic contact layer;
performing a nitridation process by a plasma treatment process to form a LaN diffusion barrier layer on the ohmic contact layer; and
sequentially forming a bottom electrode, a BLT ((BiₓLa_{y})Ti₃O₁₂) dielectric layer and a top electrode on the entire structure.

2. The method as recited in claim 1, wherein the LaN diffusion barrier layer is formed at thickness of 500 Å to 2000 Å.

3. The method as recited in claim 2, wherein the step of depositing the La or LaN layer is performed by a deposition technique selected from the group consisting of pulse laser deposition (PLD), physical vapor deposition (PVD), metal organic chemical vapor deposition (MOCVD), sputtering, plasma enhanced metal organic chemical vapor deposition (PEMOCVD), liquid source mist chemical deposition (LSMCD) and atomic layer deposition (ALD).

4. The method as recited in claim 1, wherein in the step of performing a nitridation process, the plasma treatment process is performed at a pressure of 1 mtorr to 10 torr, at a power of 25 W to 500 W and at a wafer temperature of 250° C. to 650° C.

5. The method as recited in claim 1, wherein, in the step of sequentially forming a bottom electrode, a BLT dielectric layer and a top electrode, the atomic concentration of Bi in the BLT dielectric layer is 3.25 to 3.35 and the atomic concentration of La is 0.80 to 0.90.

6. The method as recited in claim 1, wherein in the step of sequentially forming a bottom electrode, a BLT dielectric layer and a top electrode, the bottom electrode and the BLT dielectric layer are formed by a deposition technique selected from the group consisting of spin-on, physical vapor deposition, metal organics chemical vapor deposition, metal organic deposition, plasma enhanced chemical vapor deposition, liquid source mist chemical deposition and atomic layer deposition.

7. The method as recited in claim 6, wherein the plasma enhanced chemical vapor deposition is performed at a pressure of 5 mtorr to 50 torr and at a temperature of 400° C. to 700° C.

8. The method as recited in claim 6, wherein the MOD technique is carried out by steps including performing a first thermal treatment process for nucleation of the BLT layer and performing a second thermal treatment process for crystallization of the BLT layer.

9. The method as recited in claim 8, wherein the first thermal treatment process is performed by a rapid thermal process (RTP) at a speed of 80° C./second to 300° C./second and in an ambient of a reaction gas selected from the group consisting of an oxygen gas, a N₂O gas and a mixture gas of an oxygen gas and a N₂O gas.

10. The method as recited in claim 8, wherein the second thermal treatment process is performed at a temperature of 650° C. to 675° C. in an ambient selected from the group consisting of an oxygen gas, a N₂O gas and a mixture gas of oxygen gas and N₂O.

11. The method as recited in claim 1, wherein in the step of sequentially forming a bottom electrode, a BLT dielectric layer and a top electrode, the top electrode is formed of a material selected from the group consisting of IrO₂, Ru, Pt and RuOₓ, wherein x is an integer from 1 to 3.

12. The method as recited in claim 1, wherein in the step of sequentially forming a bottom electrode, a BLT dielectric layer and a top electrode, the top electrode is formed by a deposition technique selected from the group consisting of metal organic chemical vapor deposition (MOCVD), physical vapor deposition (PVD), spin-on and plasma enhanced metal organic chemical vapor deposition (PEMOCVD).

13. The method as recited in claim 1, wherein in the step of sequentially forming a bottom electrode, a BLT dielectric layer and a top electrode, the bottom electrode is formed as a type selected from the group consisting of a flat type, a cylinder type and a concave type.

14. A semiconductor device, comprising:
a semiconductor substrate;
a transistor including a gate insulating layer and a gate electrode formed on the semiconductor substrate and a source/drain region formed in the semiconductor substrate;
a contact hole exposing the source/drain region;
a plug recessed inside the contact hole;
an ohmic contact layer formed on the plug;
an LaN diffusion barrier layer formed on the ohmic contact layer;
a bottom electrode on the LaN diffusion barrier layer;
a dielectric layer formed by a BLT ((BiₓLa_{y})Ti₃O₁₂) layer on the bottom electrode; and
a top electrode formed on the dielectric layer.

15. The semiconductor device as recited in claim 14, wherein, in the BLT layer, the atomic concentration of Bi is 3.25 to 3.35 and the atomic concentration of La is 0.80 to 0.90.

16. The semiconductor device as recited in claim 14, wherein the top electrode is formed of a material selected from the group consisting of IrO₂, Ru, Pt and RuOₓ, wherein x is an integer 1 to 3.

17. The semiconductor device as recited in claim 14, wherein the bottom electrode is formed as a type selected from the group consisting of a flat type, a cylinder type and a concave type.
